(19) United States
(12) Patent Application Publication
(10) Pub. No.: US 2012/0305875 A1
(43) Pub. Date: Dec. 6, 2012

(54) PHASE-CHANGE RANDOM ACCESS MEMORY DEVICE AND METHOD OF MANUFACTURING THE SAME

(76) Inventor: Kew Chan SHIM, Ichon-si (KR)

(21) Appl. No.: 13/331,111

(22) Filed: Dec. 20, 2011

(30) Foreign Application Priority Data
May 31, 2011 (KR) 10-2011-0052436

(51) Int. Cl. H01L 21/20; H01L 45/00

(52) U.S. Cl. 257/2; 438/382; 257/E45.002; 257/E21.09

(57) ABSTRACT

A method of manufacturing a PCRAM device includes forming a switching device in a contact hole of a first interlayer insulating layer, forming a second interlayer insulating layer having an opening exposing the switching device, forming a lower electrode pattern along a sidewall of the second interlayer insulating layer to be coupled to the switching device, forming an insulating layer to be buried within the lower electrode pattern, forming a lower electrode by removing an exposed surface of the lower electrode pattern by a set height, wherein a height of a sidewall of the lower electrode is lower than that of the second interlayer insulating layer, forming a phase-change layer filing a hole of the second interlayer insulating layer from which the exposed surface of the lower electrode pattern is removed, and forming an upper electrode on the phase-change layer and a portion of the second interlayer insulating layer.

### CROSS-REFERENCES TO RELATED APPLICATION

The present application claims priority under 35 U.S.C. 119(a) to Korean patent application number 10-2011-0052436, filed on May 31, 2011, in the Korean Patent Office, which is incorporated by reference in its entirety.

### BACKGROUND OF THE INVENTION

1. Technical Field

The present invention relates to a phase-change random access memory (PCRAM) device and a method of manufacturing the same, and more particularly, to a PCRAM device including a phase-change layer and method of manufacturing the same.

2. Related Art

Phase-change random access memory (PCRAM) devices apply joule heat to a phase-change material through a heating electrode serving as a heater, thereby causing the phase-change material to be phase-changed. Data is recorded/erased using an electrical resistance difference between a crystalline state and an amorphous state of the phase-change material.

A current which is applied to change the phase-change material from the crystalline state to the amorphous state is referred to as a reset current. As the reset current is great, an operation voltage is also great. When the phase-change material is changed to the crystalline state, as a resistance at an interface between a switching device and a lower electrode, that is, a set resistance is low, a small amount of current is used to change the phase-change material.

### SUMMARY

Exemplary embodiments of the present invention relate to a phase-change random access memory (PCRAM) devices capable of enhancing phase-change reset characteristics and a method of manufacturing the same.

According to one aspect of an exemplary embodiment, a phase-change random access memory (PCRAM) device includes a semiconductor substrate in which a switching device is formed, an interlayer insulating layer having a contact hole for a lower electrode, a lower electrode formed in the contact hole to be coupled with the switching device, wherein a height of a sidewall of the lower electrode is lower than that of the interlayer insulating layer, an insulating layer formed on the lower electrode in the contact hole and isolated from the interlayer insulating layer, a phase-change layer formed on the lower electrode between the insulation layer and the interlayer insulating layer, and an upper electrode formed on the phase-change layer.

According to another aspect of an exemplary embodiment, a method of manufacturing a PCRAM device includes forming a switching device in a contact hole of a first interlayer insulating layer on a semiconductor substrate, forming a second interlayer insulating layer having an opening exposing the switching device, forming a lower electrode a pattern along a sidewall of the second interlayer insulating layer to be coupled to the switching device; forming an insulating layer to be buried within the lower electrode pattern; forming a lower electrode by removing an exposed surface of the lower electrode pattern by a set height, wherein a height of a sidewall of the lower electrode is lower than that of the second interlayer insulating layer; forming a phase-change layer filling a hole of the second interlayer insulating layer from which the exposed surface of the lower electrode pattern is removed; and forming an upper electrode on the phase-change layer and a portion of the second interlayer insulating layer.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 to 4 are cross-sectional views sequentially illustrating a method of manufacturing a phase-change random access memory (PCRAM) device according to an exemplary embodiment of the prevent invention.

### DESCRIPTION OF EXEMPLARY EMBODIMENT

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

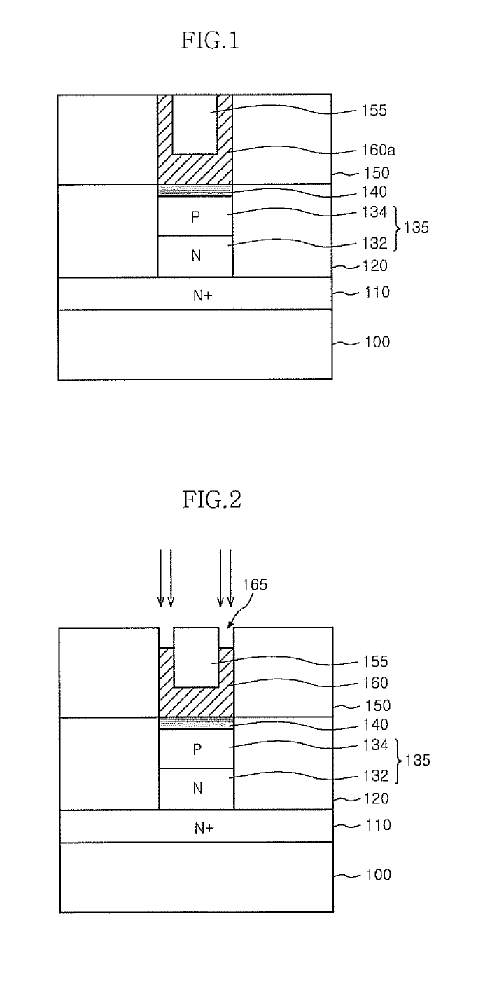

FIGS. 1 to 4 are cross-sectional views sequentially illustrating a method of manufacturing a phase-change random access memory (PCRAM) device according to an exemplary embodiment of the present invention.

Referring to FIG. 1, a switching device 135 and a lower electrode pattern 160a are formed on a semiconductor substrate 100 in which an active region 110 is formed with an n type high concentration impurity.

More specifically, the active region 110 is formed in a cell area of the semiconductor substrate 100. The active region 110 may be formed by ion-implanting an n type high concentration impurity and then performing a heat treatment process.

The active region 110 of the cell area may be simultaneously formed with a junction region (not shown) formed in a peripheral area. A first interlayer insulating layer 120 is formed on the semiconductor substrate 110 in which the active region 110 is formed.

The first interlayer insulating layer 120 may be a high density plasma (HDP) layer having dense film property and interlayer planarization property. The first interlayer insulating layer 120 is etched to expose a portion of the active region 110, thereby forming a trench.

Subsequently, a switching device 135 is formed in a trench. The switching device has a PN diode pattern including an n type selective epitaxial growth (SEG) layer 132 and a p type SEG layer 134.

Here, the n type SEG layer 132 and the p type SEG layer 134 may be formed as follows. For example, the n type SEG layer 132 is grown to be filled within a portion of the trench. Next, the p type SEG layer 134 may be formed by ion-implanting p type impurities into an upper portion of the n type SEG layer 132. The SEG layers 132 and 134 may be formed through a chemical vapor deposition (CVD) method using a hydrochloric (HCl) gas and a dichloro silane (DCS) gas. At this time, the switching device 135 is formed such that a height of the switching device 135 is lower than a height of the first interlayer insulating layer 120 and then a chemical mechanical polishing (CMP) process and a blanket etching process are performed.

With increase in an integration degree of the PCRAM device, the wiring resistance of the PCRAM device is to be lowered. To lower the wiring resistance, the PCRAM device includes a metal word line (not shown) formed on the semiconductor substrate 100 to be electrically connected to the active region 110.

The metal word line may be formed to overlap the active region 110 and compensates high resistance of the active region 110.

However, since a single crystalline growth is not performed on the metal word line, the SEG diode may not be used as the switching device 135. Therefore, when the metal word line is applied to the PCRAM device, a polysilicon diode may be used as the switching device and be referred to as a metal schottky diode.

Thus, in the exemplary embodiment, the switching diode 135 may include the metal schottky diode as well as the SEG diode. A plurality of switching devices 135 may be formed in a matrix form, that is, at a constant interval in row and column directions.

A transition metal layer (not shown) is deposited on a resultant structure of the semiconductor substrate 100 in which the switching device 135 is formed. A heat treatment is performed on the resultant structure of the semiconductor substrate 100 to selectively form an ohmic contact layer 140 on the switching diode 135.

A second interlayer insulating layer 150 having a contact hole for a lower electrode is formed on the first interlayer insulating layer 120 in which the switching device 135 is formed. At this time, the second interlayer insulating layer 150 may include a nitride material. Here, the contact hole for a lower electrode according to the exemplary embodiment is an opening exposing the switching device 135.

Subsequently, the pattern 160a for a lower electrode and a nitride layer 155 are formed within the contact hole for a lower electrode of the second interlayer insulating layer 150.

More specifically, a material layer for a lower electrode (not shown) and a nitride material layer are sequentially formed along a surface of the contact hole for a lower electrode and then a CMP process is performed to form the pattern 160a for a lower electrode and the nitride layer 155 filling the contact hole for a lower electrode. At this time, the pattern 160a for a lower electrode may be formed to be in contact with a lateral side of the second interlayer insulating layer 150 as a ring or pillar type and to remain on the ohmic contact layer 140 in the lower portion.

For example, the material layer for lower electrode may include at least one material selected from the group consisting of a metal layer such as tungsten (W), titanium (Ti), molybdenum (Mo), tantalum (Ta), and platinum (Pt), a metal nitride layer such as titanium nitride (TiN), tantalum nitride (TaN), tungsten nitride (WN), molybdenum nitride (MoN), Niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), and tantalum aluminum nitride (TaAlN), a silicide layer such as titanium silicide (TiSi) and tantalum silicide (TaSi), an alloy layer such as titanium tungsten (TiW), and a metal oxide (nitride) layer such as titanium oxynitride (TiON), titanium aluminum oxynitride (TiAlON), tungsten oxynitride (WON), tantalum oxynitride (TaON), and iridium oxide (IrO₂).

Referring to FIG. 2, a lower electrode 160 having a lower height than the second interlayer insulating layer 150 is formed on a resultant structure of the semiconductor substrate 100.

More specifically, an etch-back process is performed on the resultant structure of the semiconductor substrate 100 having the pattern 160a to partially remove an exposed portion of the pattern 160a. Therefore, the lower electrode 160 having the lower height than the second interlayer insulating layer 150 may be formed. That is, the lower electrode 160 according to the exemplary embodiment of the present invention may be formed such that heights of the both side portions of the lower electrode 160 are lower than that of the second interlayer insulating layer 150.

At this time, the partially removing the exposed upper portion of the pattern 160a for a lower electrode is to ensure a space where a phase-change layer 170 is to be formed later, in order for the pattern 160a to be inlaid with the phase-change layer 170.

A hole 165 is formed on the lower electrode 160 by partial removal of the pattern 160a.

To form the lower electrode 160 having the lower height of the both side portions thereof than the second interlayer insulating layer 150, that is, to remove the exposed upper surface of the pattern 160a, a cleaning process using an etching process may be performed.

As an etching material to selectively etch the pattern 160a for a lower electrode, a binary system hydrofluoric material such as hydrofluoric acid (HF), beryllium fluoride (BeF₂), boron-trifluoride (BF₃), tetrafluoromethane (CF₄), nitrogen trifluoride (NF₃), oxygen fluoride (OF₂), and chlorofluoride (ClF) may be used.

At this time, the removed height of the pattern 160a is, for example, equal to or greater than 90 Å and less than 120 Å.

In general, the lower electrode 160 causes a phase-change material to be phase-changed by providing Joule heat to the phase-change material and data is recorded/erased using an electrical resistance difference between a crystalline state and an amorphous state of the phase-change material.

According to one exemplary embodiment, even when the lower electrode 160 having a cylinder shape which has the lower height than the second interlayer insulating layer 150 is formed, the lower electrode 160 may have the same contact area with a phase-change layer 170 or the switching device 135, compared to the conventional art.

The degree of controlling the height of the lower electrode 160 to be lower than that of the second interlayer insulating layer 150 is not limited to one exemplary embodiment of the present invention. The removal height of the lower electrode 160 may be increased/reduced enough for changing the phase-change material from the crystalline state to the amorphous state.

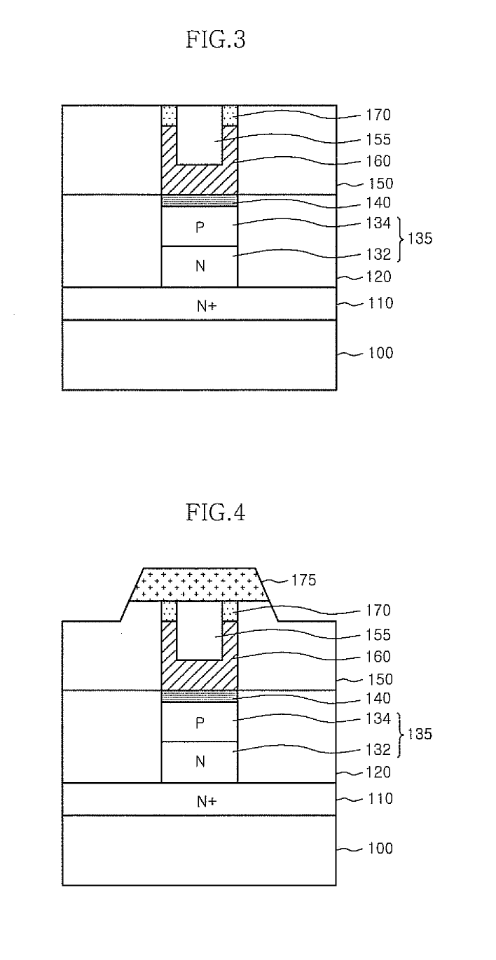

Referring to FIG. 3, a phase-change layer 170 filling the hole 165 on the lower electrode 160 is formed.

More specifically, a phase-change material layer (not shown) is grown on a resultant structure of the semiconductor substrate 100 in which the lower electrode 160 is formed using any one deposition method of a CVD method and an atomic layer deposition (ALD) method. Then, a CMP process or an etching process is performed to form the phase-change layer 170 buried within the hole 165 on the lower electrode 160. According to the exemplary embodiment, a height of the phase-change layer 170 may be, for example, 90 Å to 120 Å.

At this time, as the phase-change material layer, a binary system material layer such as antimony-tellurium (Sb—Te) and Germanium-tellurium (Ge—Te) or a ternary system material layer such as Ge—Sb—Te may be used.

The exemplary embodiment of the present invention illustrates that the phase-change material layer 170 is formed by the CMP process, but the exemplary embodiment is not limited to the CMP process as the process of forming the phase-change material 170. In some embodiments, an etching process is formed on the phase-change material layer to form the phase-change layer 170. For example, the phase-change layer 170 is formed by the etching process, and the chlorine (Cl2) may be used as an etching material.

Since the phase-change layer 170 according to an exemplary embodiment of the present invention is formed within a restricted space, that is, the hole formed by the lower electrode 160, a programming volume of the phase-change material may be reduced. Thus, the PCRAM device reduces a reset current to reduce power consumption and increase an operation speed.

Referring to FIG. 4, an upper electrode 175 is formed on the semiconductor substrate 100 in which the phase-change layer 170 is formed.

More specifically, an upper electrode material layer (not shown) may be deposited on a resultant structure of the semiconductor substrate 100 in which the phase-change layer 170 is formed and then patterned to form the upper electrode 175. At this time, the exposed surface of the second interlayer insulating layer 150 may be also etched so that a height of the second interlayer insulating layer 150 is equal to those of the both side portions of the lower electrode 160.

According to an exemplary embodiment of the present invention, the upper electrode material layer may be formed of, for example, a Ti layer or a TiN layer to be electrically connected to the phase-change layer 170.

The PCRAM device according to the exemplary embodiment of the present invention separately etches the phase-change layer 170 and the upper electrode 175 to prevent an etching damage of the phase-change material from being caused due to an etching of the upper electrode 175, thereby increasing the reliability of the device.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A method of a phase-change random access memory (PCRAM) device, comprising:
forming a switching device in a contact hole of a first interlayer insulating layer on a semiconductor substrate;
forming a second interlayer insulating layer having an opening exposing the switching device;
forming a lower electrode pattern along a sidewall of the second interlayer insulating layer to be coupled to the switching device;
forming an insulating layer to be buried within the lower electrode pattern;
forming a lower electrode by removing an exposed surface of the lower electrode pattern by a set height, wherein a height of a sidewall of the lower electrode is lower than that of the second interlayer insulating layer;
forming a phase-change layer filling a hole of the second interlayer insulating layer from which the exposed surface of the lower electrode pattern is removed; and
forming an upper electrode on the phase-change layer and a portion of the second interlayer insulating layer.

2. The method of claim 1, wherein the insulating layer includes a nitride material.

3. The method of claim 1, wherein the set height is equal to or greater than 90 Å and equal to or less than 120 Å.

4. The method of claim 1, wherein an etching material to remove the exposed surface of the lower electrode pattern is a binary system hydrofluoric material including hydrofluoric acid (HF), beryllium fluoride (BeF₂), boron-trifluoride (BF₃), tetrafluoromethane (CF₄), beryllium fluoride (BeF₂), boron-trifluoride (BF₃), tetrafluoromethane (CF₄), nitrogen trifluoride (NF₃), oxygen fluoride (OF₂), chlorofluoride (ClF).

5. The method of claim 1, wherein a height of the phase-change layer is equal to or greater than 90 Å and equal to or less than 120 Å.

6. The method of claim 1, wherein the forming of the phase-change layer includes:
growing a phase-change material layer on a resultant of the semiconductor substrate in which the second interlayer insulating layer is formed; and
performing a planarization process to form the phase-change layer buried in the hole of the second interlayer insulating layer.

7. The method of claim 1, wherein the forming of the phase-change layer includes:
growing a phase-change material layer on a resultant of the semiconductor substrate in which the second interlayer insulating layer is formed; and
performing an etching process on an entire surface of the semiconductor substrate, in which the phase-change material layer is formed, to form the phase-change layer buried in the hole of the second interlayer insulating layer.

8. The method of claim 7, wherein an etching material for the etching process of forming the phase-change layer includes chloride (Cl₂).

9. A phase-change random access memory (PCRAM) device, comprising:
a semiconductor substrate in which a switching device is formed;
an interlayer insulating layer having a contact hole for a lower electrode;
a lower electrode formed in the contact hole to be coupled with the switching device, wherein a height of a sidewall of the lower electrode is lower than that of the interlayer insulating layer;
an insulating layer formed on the lower electrode in the contact hole and isolated from the interlayer insulating layer;
a phase-change layer formed on the lower electrode between the insulation layer and the interlayer insulating layer; and
an upper electrode formed on the phase-change layer.

10. The PCRAM device of claim 9, wherein the insulating layer is partially buried within the lower electrode and the lower electrode surrounds lower portion of the insulating layer.
